(19) United States
(12) Patent Application Publication
(10) Pub. No.: US 2010/0295064 A1
(43) Pub. Date: Nov. 25, 2010

(54) ORGANIC LIGHT EMITTING DIODE DEVICE

(75) Inventors: Hans-Peter Loebl, Monschau-Imgenbroich (DE); Wofgang Otto Budde, Aachen (DE); Dietrich Bertram, Aachen (DE)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/445,755

(22) PCT Filed: Oct. 10, 2007
(86) PCT No.: PCT/IB07/54128

§ 371 Date: Apr. 16, 2009

(30) Foreign Application Priority Data
Oct. 20, 2006 (EP) 06122642.9

(51) Int. Cl. H01L 31/12

(52) U.S. Cl. 257/84; 257/E33.077

(57) ABSTRACT

The invention relates to an organic light emitting diode device (1) comprising a substrate material (10) as a carrier, which is coated and/or superimposed by a lower electrode layer (11), at least one emitting material layer (12) for light emitting and an upper electrode layer (13), whereas the upper electrode layer (13) features light reflectance, in order to pass the emitted light through the substrate material (10), whereas said device (1) comprises a light sensor (14) for detecting the luminous intensity of the emitted light.

The present invention relates to an organic light emitting diode device comprising a substrate material as a carrier, which is coated and/or superimposed by a lower electrode layer, at least one emitting material layer for light emitting and an upper electrode layer, whereas said device comprises a light sensor for detecting the luminous intensity of the emitted light.

In the recent years organic light emitting diodes (OLED) are of great interest as superior flat-panel systems. These systems utilize current passing through a thin-film of organic material to generate light. The color of the emitted light and the efficiency of the energy conversion from current to light are determined by the composition of the organic thin-film material. Thus, the OLEDs comprise a substrate material, which is used as a carrier part, and which may be made of glass or an organic material or from a non-transmittive material such as metal foils in the case of top-emitting OLEDs. Furthermore, organic light emitting diodes consist of a very thin layer with a layer thickness of approximately 100 nm of organic substances or a glass substrate covered with an electrically conducting and optically transparent oxide. This organic layer is usually performed as an Indium-Tin-Oxide (ITO).

Usually, one electrode layer is performed as the anode layer and one electrode layer is performed as the cathode layer. The anode layer, formed by an ITO-material layer, is arranged adjacent to the substrate material. The next layer is the emitting material layer, which is performed as a plurality of different layers, forming the active light emitting part of the entire device. On the top of the emitting material layer the upper electrode layer is deposited, which forms the cathode layer. According to relevant materials for the electrode layers, the anode layer is preferred to be made of said ITO-layer and the cathode layer is embodied as an aluminium layer, whereas the aluminium layer features a thickness of approximately 100 nm and thus a thickness like the ITO-layer (ITO=Indium Tin Oxide). Depending on the thickness of each layer and depending on the material composition, the light, emitted by the emitting material layer, leaves the device by passing the lower electrode layer or the upper electrode layer (top emission). Thus, the emitted light may pass the substrate material, and the upper electrode layer forms a mirror. In this case, the ITO-layer is transparent. Otherwise, it is possible, that the cathode metal is thin enough to be partially transparent, and a part of the emitted light can also be passed through the cathode. In another embodiment the cathode is positioned on the glass substrate consisting of a thick Aluminium layer, which reflects the light. Subsequently the organic transport and emission layer is deposited and the anode can be located on top of the stack. This anode can consist of a thin Silver film (semitransparent) with an optical layer, which enhances the transmission of light. The latter layer (optional) can be formed from ZnSe or ZnS or a material with similar optical properties.

Between the anode layer, which is e.g. the Indium-Tin-Oxide (ITO) layer and the cathode layer like the aluminium layer are arranged several functional layers, which forms the emitting material layer. These layers may concern fluorescent and/or phosphorescent emitter layers, a hole blocking layer, an electron transport layer, a hole transporting layer and/or additionally a hole injection layer and/or additionally an electron injection layer, whereas these layers feature a thickness of approximately 5 nm to 100 nm. The OLED may also consist of a stack of OLEDs as described above, which are separated by conductive layers such as ITO or thin metal films or by so-called charge generation layers, which consist of p-doped and n-doped layers with and without barrier layers in between. Depending on the layers stack the top emission, which emits by passing the aluminium cathode or a bottom emission by passing the light through the ITO-layer may represent different types of organic emitting diodes.

During the lifetime of organic light emitting diodes the luminance level of the emitted light may decrease by a given operating voltage. To compensate aging effects and to keep the luminance level constant over the lifetime, a feedback loop is needed, which increases the applied voltage. This feedback loop requires a sensing element, measuring the output light, emitted by the organic light emitting diode. In particular, if the organic light emitting diode device is arranged within a plurality of devices, each forming an emitting tile, the control of the brightness level of the individual tiles is important, when a homogeneous appearance of the large area of emitting light is desired. The light tiles can be steered also in such a way that deliberately inhomogeneous light effects can be achieved. Also OLED applications in which the color point of the light has to be controlled or varied require the use of a light-sensing element.

The patent application publication US 2003/0047736 A1 discloses an organic light emitting diode device comprising a light sensor for detecting the luminous intensity of the light emitted from the light emitting element. The light emitting element includes a lower electrode, which is performed as a reflective layer, and an upper electrode layer having light transparency, and in between the lower electrode layer and the upper electrode layer the light emitting layer is arranged. The light sensor is arranged on the top of the transparent upper electrode layer, in order to detect the emitted light, which is passing through the upper electrode layer.

Indeed, it is possible to detect the intensity of the emitted light, but unfortunately the light sensor is arranged within the emitting field of the OLED device. Due to the arrangement of the light sensor within the light emitting field the light sensor may appear as a dark region or a dark spot. The appearance of a dark region or a dark spot within the emitting field the homogeneous emitting appearance of the entire device is affected in a negative way.

When the device is formed as an emitting tile in an arrangement of a plurality of emitting devices, each emitting tile comprises a dark spot. Furthermore, a light sensor switching element for switching whether or not luminous intensity information supplied in the form of a current or a voltage from the light sensor is necessary according to the disclosed OLED system. The switching element is arranged adjacent to the active layers of the OLED, and obstructs a homogeneous appearance of a light emitting field, emitted by a plurality of devices, arranged one next to the other in a kind of a matrix. Moreover, the electrical contacting of the light sensor is problematically, because the electrically contacting only may be realized by the switching element.

Thus, the invention has the objective to eliminate the above mentioned disadvantages. In particular it is an objective of the present invention to provide an organic light emitting diode, featuring a high evenness in luminance over the lifetime. Moreover, it is the objective of the present invention to provide an organic light emitting diode device, performed to be arranged as an emitting tile in a plurality of devices, featuring a homogenous light emitting appearance.

This objective is achieved by an organic light emitting diode device as taught by claim 1 of the present invention. A preferred embodiment of the invention is defined by the subclaims.

The invention discloses that the upper electrode layer features a light reflectance, in order to pass the emitted light through the substrate material. Thus, the light sensor does not appear within the emitting field of the OLED device. The light passes through the lower electrode layer and the substrate material, because the upper electrode layer is performed as a mirror. This advantage can only be reached by combining a bottom emitting OLED and said light sensor. The bottom emitting describes the emitting of the light by passing the lower electrode layer and the substrate material.

As a preferred embodiment the light sensor is arranged onto the upper electrode layer. By applying the light sensor onto the upper electrode layer the light sensor does not disturb the propagation of the emitted light. The light may propagate from the emitting material layer through the lower electrode layer and thus through the substrate material, and the advantage is obtained, that the light sensor does not appear as a dark spot or a dark region within the emitting field.

According to another preferred embodiment the upper electrode layer features a hole, which is formed below the light sensor for passing the emitted light into the light sensor. By forming a hole into the upper electrode layer the region of the hole has not the effect of a mirror, and the emitted light of the emitting material layer is not reflected towards the substrate material. The not reflected light passes the hole and illuminates the light sensor.

Advantageously, the light sensor comprises an active optical area, whereas the emitted light illuminates said active optical area by passing said hole. The hole may feature a diameter of 0.05 to 2 mm, preferred 0.07 to 1.5 mm and most preferred 0.1 to 0.5 mm. Likewise, an oblong shape or any different shape of the hole is feasible. The smaller the hole, the less the hole appears in the entire emitting field as a non-reflecting area.

According to another preferred embodiment of the present invention the light sensor comprises at least one electrical lead providing a first electrical contact to the light sensor, whereas a second electrical contact is formed by the upper electrode layer itself. The upper electrode layer is made of a conductive material, thus, it is possible to contact the light sensor by way of the upper electrode layer. The second contact is formed by a lead, a contact pin or a contact pad on the top surface of the light sensor.

According to another preferred embodiment, the substrate material is bordered by a lateral face, and said light sensor is arranged on the lateral face. The substrate material is shaped as an oblong or quadrate carrier part, which is bordered by at least four lateral faces. When the emitted light passes the substrate material, the light attains the lateral faces, since a fraction of the emitted light is guided inside the substrate material, which is performed as a glass or plastic material. The guidance of the light is caused by internal reflection within the substrate material, and propagates towards the lateral faces.

The optical area of the sensor is arranged towards the lateral face, and the emitted light is enabled to illuminate the active optical area. The electrical contact of the light sensor is realized by two electrical leads, because the substrate material is not electrically conductive and thus may not be utilized as an electrical contact to the sensor. But the arrangement of the leads can be provided as thin strip conductors along the lateral face, and the light sensor is not obstructive for performing the device as an emitting tile.

Yet another embodiment of the present device can be seen in arranging the light sensor between the lower electrode layer and the emitting material layer. Thus, the light sensor is embodied as a surface mounted device on the top of the first electrode layer. The active area of the sensor is directed towards the organic light emitting layers of the OLED. By applying different coating processes, the first coating on the top surface of the substrate material comprises the lower electrode layer, which is followed by applying the light sensor on the top surface of the lower electrode layer. Subsequently, the emitting material layer is applied on the top surface of the lower electrode layer and the light sensor, which forms a smoothly and uninterrupted transition between the emitting material layer on the lower electrode layer to the surface of the light sensor. Thus, the active optical area of the light sensor is arranged towards the emitting material layer. A measuring of the light, emitted by the emitting material layer on the top surface of the light sensor enables reliable information of the luminance level of the entire emitting field.

Advantageously, the lower electrode layer is patterned, by what said light sensor is electrically contacted by the lower electrode layer due to at least two electrically separated areas within the electrode layer. The patterned lower electrode layer comprises electrically separated areas, which may supply a measuring current or a measuring voltage to the light sensor. The electrically contacting between the light sensor and the lower electrode layer may be realized by a conductive gluing or soldering bolds between the sensor and the layer. Thus, a first electrically separated part of the lower electrode layer may form the first electrically contact and a second electrically separated part of the lower electrode layer, which forms the real anode layer, forms the second electrically contacting of the light sensor.

Another preferred embodiment of the present invention comprises a light sensor, which is glued and/or soldered by applying soldering balls onto the at least one layer and/or the substrate material. The gluing can comprise an electrically contacting by applying electrically conductive glue. The soldering of the light sensor onto the at least one layer forms a kind of surface mounted device, because the light sensor is soldered onto the top surface of the layer. The light sensor comprises at least one photodiode, which is performed as the active optical area. The light sensing surface of the at least one photodiode may be arranged towards the top surface or the bottom surface of the light sensor body.

Yet another embodiment of the present invention provides an OLED device, which is formed as an emitting tile in an arrangement of a plurality of devices, forming a matrix of a plurality of tiles, which may emit light with a homogeneous luminance level.

Additional details, characteristics and advantages of the objective of the invention are disclosed in the subclaims and the following description of the respective figures—which are only shown in an exemplary fashion—show preferred embodiments of the invention, which will be described in conjunction with the accompanying figures, in which:

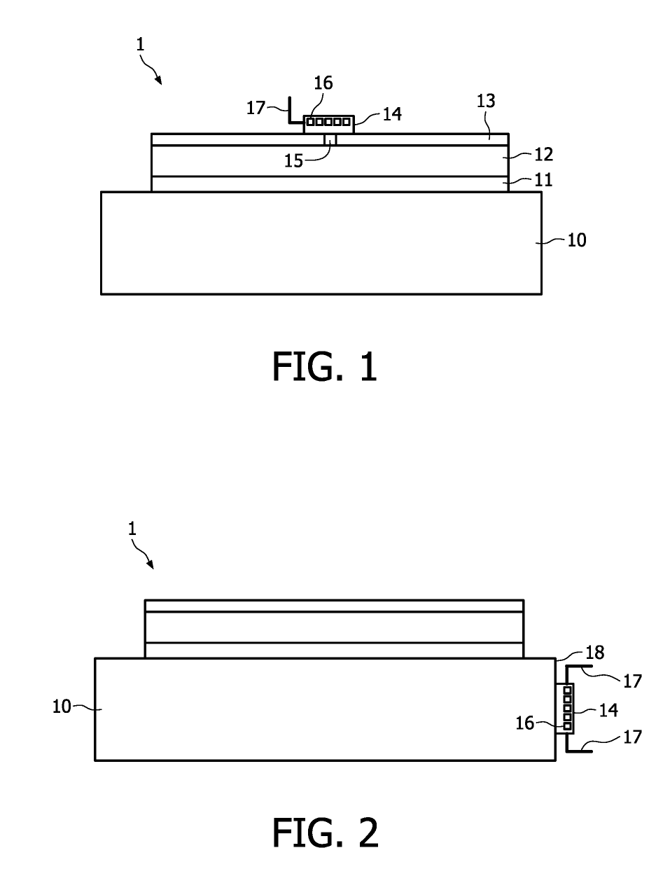

FIG. 1 shows an organic light emitting diode in a cross sectioned side view with a light sensor, which is arranged on the reverse side of the upper electrode layer;

FIG. 2 shows a light sensor, which is arranged on a lateral face of the substrate material;

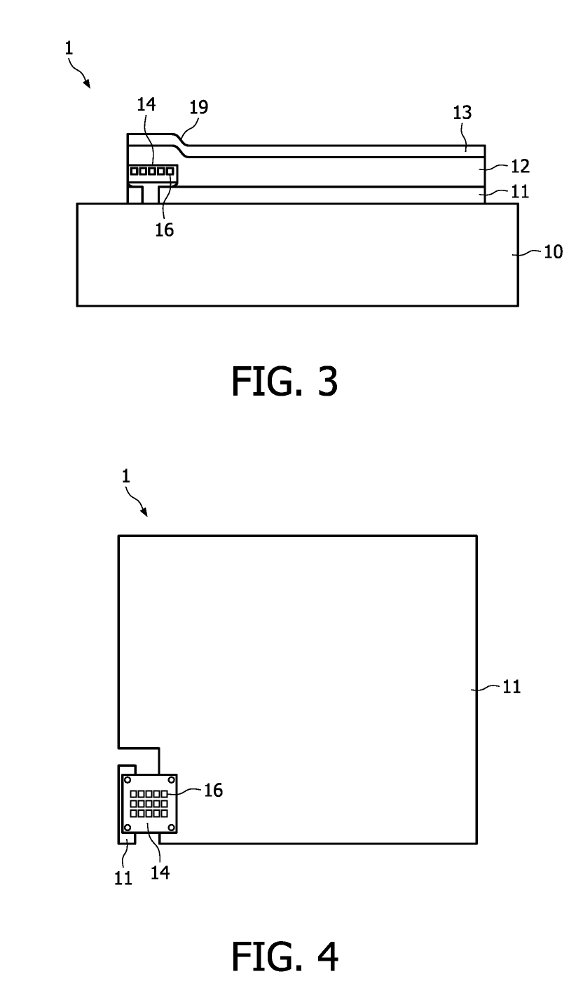

FIG. 3 shows another embodiment of the arrangement of the light sensor between the lower electrode layer and the emitting material layer; and

FIG. 4 shows a top view of the arrangement of the light sensor according to FIG. 3.

The organic light emitting diode device 1 is shown in a cross sectioned side view. On the bottom is shown the substrate material 10, which may feature a thickness of 1 to 2 mm and comprises a glass- or synthetic material. On the top surface of the substrate material 10 is deposited a lower electrode layer 11, which may be performed as a transparent ITO-anode layer.

On the lower electrode layer 11 is deposited an emitting layer 12, which consists of several functional layers, which may be a hole injection layer, a hole transparent layer, an emission layer, which may be performed as a fluorescent and/or phosphorescent emitter layer, a hole blocking layer, an electron transport layer, a hole transport layer and/or additionally an electron injection layer, and/or additionally a hole injection layer whereas these layers may feature a thickness of approximately 5 nm to 100 nm. The final layer is an upper electrode layer 13, which may be performed as an aluminum layer or silver layer and forms the cathode layer. The upper electrode layer 13 features a high reflectivity for the emitted light. Thus, the light, emitted by the emitting material layer 12 reflects on the upper electrode layer 13 and propagates towards the substrate material 10.

On the top of the upper electrode layer 13 a light sensor 14 is applied. In order to enable the emitted light passing through the upper electrode layer 13, a hole 15 is performed in the upper electrode layer 13. The hole 15 may feature a diameter of 0.1 to 0.5 mm, whereas the light sensor 14 is arranged squarely onto the hole 15. The light sensor 14 comprises an active optical area 16, and the light, which passes through the hole 15, may illuminate the active optical area 16, whereas the active optical area 16 can be performed as a photodiode.

The electrical contacting of the light sensor 14 may be realized by an electrical lead 17, whereas the electrical lead 17 provides a first electrical contact to the light sensor 14. A second electrical sensor is formed by the upper electrode layer 13 by itself. The light sensor is integrated into an electrically feedback loop, in order to compensate aging effects and to keep the luminance level constant over the service time of the organic light emitting diode device 1 (the feedback loop is not shown).

FIG. 2 shows the organic light emitting diode 1 with an alternative arrangement of the light sensor 14. The light sensor 14 is applied on a lateral face 18, which forms a lateral border of the substrate material 10. The sensor 14 is glued on the lateral face 18, whereas the emitted light, which passes the substrate material, features a fraction, which is guided inside the substrate material 10 by total internal reflection and will attain the lateral face 18 and thus may propagate into the active optical area 16 of the light sensor 14. In order to provide an electrical contacting of the light sensor 14, it comprises two electrical leads 17, which are shown as two pins on two sides of the sensor 14. Theses two electrical leads 17 are shown only in an exemplary fashion, and can be alternatively performed as conductive stripes on the lateral face 18 of the substrate material 10.

Yet another embodiment of the arrangement of the light sensor 14 is given in FIG. 3. FIG. 3 shows an organic light emitting diode device 1 with a light sensor 14, arranged between the lower electrode layer 11 and the emitting material layer 12. According to this arrangement the light sensor 14 is performed as a surface mounted device, mounted onto the lower electrode layer 11. Usually, the layers 11 to 13 are deposited onto the substrate material 10 by PVD-, CVD- or similar methods, whereas the light sensor 14 may be applied between the depositing step of the lower electrode layer 11 and the depositing step of the emitting material layer 12. Due to the arrangement of the light sensor 14, the emitting material layer 12 and the upper electrode layer 13 features a kind of obstacle 19, in order to pass or to lay over the light sensor 14. The emitting behavior of the emitting material layer 12 on the top of the light sensor 14 is similar to the emitting behavior of the entire emitting material layer 12, and the measuring of the luminance level is as reliable as applying the light sensor 14 at any different arrangements. Due to the arrangement of the light sensor 14 on the top of the lower electrode layer 11, the lower electrode layer 11 may be patterned, by what the light sensor 14 is electrically contacted by the lower electrode layer 11. The patterning may be performed as an electrically separation of the lower electrode layer 11 into at least two regions for contacting the optical sensor 14.

FIG. 4 shows a top view of the arrangement of the light sensor 14 according to FIG. 3. The light sensor 14 comprises an active optical area 16, which is illuminated by the emitted light. The lower electrode layer 11 is divided into a patterned part on the left side of the light sensor 14 and the entire lower electrode layer 11. The light sensor 14 is electrically contacted to both of the parts of the lower electrode layer 11, and can be electrically contacted by way of contacting the lower electrode layers 11 as described above.

The present invention is not limited by the embodiment described above, which is represented as an example only and can be modified in various ways within the scope of protection defined by the appending patent claims. Thus, the invention is also applicable to different embodiments, in particular of the design of the OLED-device and/or the device of the light sensor 14. Another embodiment can be seen in applying the light sensor 14 on the top of the substrate material 10, followed by the lower electrode layer 11, the emitting material layer 12 and the upper electrode layer 13. Thus, the light sensor 14 can be electrically contacted by a patterned lower electrode layer 11, whereas the contacting of the sensor 14 is arranged on the same side as the active optical area 16, arranged towards the emitting material layer 12.

### LIST OF NUMERALS

1 organic light emitting diode device
10 substrate material
11 lower electrode layer
12 emitting material layer
13 upper electrode layer
14 light sensor
15 hole
16 active optical area
17 electrical lead
18 lateral face
19 obstacle

1. An organic light emitting diode device (1) comprising a substrate material (10) as a carrier, which is coated and/or superimposed by a lower electrode layer (11), at least one emitting material layer (12) for light emitting and an reflective upper electrode layer (13) for passing the emitted light through the substrate material (10), wherein said device (1) comprises a light sensor (14) for detecting the luminous intensity of the emitted light.

2. A device (1) according to claim 1, wherein the light sensor (14) is arranged onto the upper electrode layer (13).

3. A device (1) according to claim 1, wherein the upper electrode layer (13) defines a hole (15) formed below the light sensor (14) for passing the emitted light into the light sensor (14).

4. A device (1) according to claim 3, wherein the light sensor (14) comprises an active optical area (16), such that the emitted light illuminates said active optical area (16) through said hole (15).

5. A device (1) according to claim 1, wherein the light sensor (14) comprises at least one electrical lead (17) providing a first electrical contact to the light sensor (14), a second electrical contact being formed by the upper electrode layer (13).

6. A device (1) according to claim 1, wherein the substrate material (10) is bordered by a lateral face (18), and said light sensor (14) is arranged on the lateral face (18).

7. A device (1) according to claim 1, wherein the light sensor (14) is arranged between the lower electrode layer (11) and the emitting material layer (12), thus the light sensor (14) is embodied as a surface mounted device.

8. A device (1) according to claim 7, wherein the lower electrode layer (11) is patterned, by what said light sensor (14) is electrically contacted by the lower electrode layer (11) due to at least two electrically separated areas within the electrode layer (11).

9. A device (1) according to claim 7, wherein the active optical area (16) is arranged towards the emitting material layer (12).

10. A device (1) according to claim 1, wherein the light sensor (14) is glued and/or soldered onto the at least one layer (11, 13) and/or the substrate material (10).

11. A device (1) according claim 1, wherein the light sensor (14) comprises at least one photodiode.

12. A device (1) according to a claim 1, wherein the device (1) is formed as an emitting tile in an arrangement of a plurality of devices (1).
